(19) United States
(12) Patent Application Publication
(10) Pub. No.: US 2014/0003571 A1
(43) Pub. Date: Jan. 2, 2014

(54) SHIFT REGISTER CIRCUIT, ELECTRO-OPTICAL DEVICE AND ELECTRONIC APPARATUS

(71) Applicant: SEIKO EPSON CORPORATION, Tokyo (JP)

(72) Inventor: Kuni YAMAMURA, Chino-shi (JP)

(21) Appl. No.: 13/923,742

(22) Filed: Jun. 21, 2013

(30) Foreign Application Priority Data
Jun. 28, 2012 (JP) 2012-145112

(51) Int. Cl. G11C 19/28

(52) U.S. Cl. CPC G11C 19/28
USPC 377/74

(57) ABSTRACT

A shift register includes first type D latches in the odd-numbered stage and second type D latches in the even-numbered stage. A pass gate of the first type D latch and a memory controller of the second type D latch are made from a first conductivity type transistor, and a memory controller of the first type D latch and a pass gate of the second type D latch are made from a second conductivity type transistor.

### BACKGROUND

1. Technical Field

The present invention relates to a shift register circuit, an electro-optical device and an electronic apparatus.

2. Related Art

A projector is an electronic apparatus that emits light to a transmission type electro-optical device or a reflection type electro-optical device, and projects the transmission light or the reflection light modulated by these electro-optical devices on a screen. The projector is the electronic apparatus that is configured in such a manner that the light emitted from a light source is condensed and is incident on the electro-optical device, and the transmission light or the reflection light modulated according to an electric signal is enlargedly projected onto the screen through a projection lens. The projector has an advantage of displaying a large screen image. As the electro-optical device used in such an electronic apparatus, a liquid crystal device is known. The liquid crystal device forms an image by using dielectric anisotropy of liquid crystal and rotary polarization of light in a liquid crystal layer.

One example of the liquid crystal device is disclosed in JP-A-2005-166139. In a circuit block diagram illustrated in FIG. 1 in JP-A-2005-166139, scan lines and signal lines are arranged in an image display region. Pixels are arranged, in rows and columns, in intersection points of the scan lines and the signal lines, and a scan line drive circuit and a data line drive circuit that supply a signal to each pixel are formed in the vicinity of the image display region. A shift register circuit, which is controlled with a clock signal, is included in the scan line drive circuit and the specific scan line is selected from among the multiple scan lines. The clock signal is generated in a clock signal generation circuit. One example of the shift register circuit is disclosed in JP-A-11-282426. In a circuit configuration diagram illustrated in FIG. 2 in JP-A-11-282426, a clock signal CLX and an inversion clock signal CLX_{INV}, which are mutually complementary, are provided to a shift register circuit and thus the scan line is selected.

Furthermore, in the liquid crystal device, there is a case where every scan line is selected or a case where every two scan lines are selected as disclosed in JP-A-2012-49645, according to a display method used in the liquid crystal device.

However, when the clock signals disclosed in JP-A-11-282426 are provided to the liquid crystal device disclosed in JP-A-2005-166139, and additionally, the display method of selecting every two scan lines, which is disclosed in JP-A-2012-49645, is employed, there occurs a vertical band that horizontally divides the image display region into two parts. In other words, in the electro-optical device in the related art, there is a problem in that a high-grade image display is difficult to perform.

In addition, because the clock signal generation circuit is necessary in the shift register circuits disclosed in JP-A-2005-166139 and JP-A-11-282426, there is a problem in that a system-wide circuit scale is increased. Furthermore, in the shift register circuit disclosed in JP-A-11-282426, there is a problem in that the shift register circuit is easy to malfunction due to a phase difference between the clock signal CLX and the inversion clock signal CLX_{INV}.

### SUMMARY

The invention can be realized in the following forms or application examples.

According to an application example, there is provided a shift register circuit including p (p is an integer that is 2 or greater) D latches, and a clock line, in which each of the p D latches includes a local input portion and a local output portion, in which the local output portion of the i-th (i is an integer from 1 to (p−1)) D latch and the local input portion of the (i+1)-th D latch are electrically connected to each other, in which each of the p D latches includes, at least a pass gate, 2k (k is an integer that is 1 or greater) inverters, and a memory controller, in which the pass gate and the 2k inverters are electrically connected in series between the local input portion and the local output portion, the memory controller is eletrcially connected in parallel to the 2k inverters between the pass gate and the local output portion, and a control electrode of the pass gate and a control electrode of the memory controller are electrically connected to the clock line, in which the p D latches in the odd-numbered stage are first type D latches and the p D latches in the even-numbered stage are second type D latches, in which wherein the pass gate of the first type D latch is made from a first conductivity type transistor and the memory controller of the first type D latch is made from a second conductivity type transistor, and in which the pass gate of the second type D latch is made from the second conductivity type transistor, and the memory controller of the second type D latch is made from the first conductivity type transistor.

With this configuration, the shift register circuit can be driven with one clock signal (referred to as a single phase clock). That is, there is no need to prepare for two types of clock signals that are mutually complementary and that are equal in phase, and therefore a clock signal generation circuit can be unnecessary and a system-wide circuit scale can be decreased. Furthermore, when the clock signals are two kinds, the shift register circuit malfunctions due to the phase difference between two kinds of clock signals, but because the single phase clock is possible with this configuration, a stable circuit operation can be realized without an occurrence of such a malfunction of the shift register circuit.

In the shift register circuit according to the application example, it is preferable that one of source and drain regions of the pass gate be the local input portion, and the other of the source and drain regions of the pass gate and one of source and drain regions of the memory controller be electrically connected to each other, and that the other of the source and drain regions of the memory controller be the local output portion, the control electrode of the pass gate be a gate electrode, and the control electrode of the memory controller be a gate electrode.

With this configuration, the pass gate and the memory controller can be controlled with the clock signal. When the pass gate allows the passing of the data, the memory controller may cause the 2k inverters to function as the buffer circuits, and when the pass gate disallows the passing of the data, because the memory controller causes the 2k inverters to function as the storage circuits, the D latch can be caused to correctly function and the shift register circuit can be caused to correctly operate.

In the shift register circuit according to the application example, it is preferable that each of the 2k inverters includes an inverter input electrode and an inverter output electrode, in which the inverter output electrode of the n-th (n is an integer from 1 to (2k−1)) inverter and the inverter input electrode of the (n+1)-th inverter be electrically connected to each other, in which the inverter input electrode of the first inverter, the other of the source and drain regions of the pass gate, and the one of the source and drain regions of the memory controller be electrically connected to each other, and in which the inverter output electrode of the 2k-th inverter and the other of the source and drain regions of the memory controller be electrically connected.

With this configuration, because the local input portion and the local output portion are electrically connected with the 2k inverters, and the memory controller is electrically connected between the inverter input electrode of the first inverter and the inverter output electrode of the 2k-th inverter, the 2k inverters can be properly used as the buffer circuit or the storage circuit for different purposes, according to the clock signal. Therefore, the D latch can be caused to correctly function, and the shift register circuit can be caused to correctly operate.

In the shift register circuit according to the application example, it is preferable that the first conductivity type transistor be an N-type transistor, and the second conductivity type transistor be a P-type transistor.

The N-type transistor has higher conductance than the P-type transistor. When a comparison is made between the pass gate and the memory controller, because while the pass gate allows the passing of the data in an ON state, the memory controller retains the data in the ON state, the pass gate is required to have higher conductance than the memory controller. With this configuration, because the pass gate of the first type D latch positioned in the odd-numbered stage is configured from the N-type transistor, in a case where the number of the D latches is odd in the shift register circuit, the number of the N-type transistors that make up the pass gates can be more than the number of the P-type transistors that make up the pass gates. In addition, the local input portion of the D latch in the first stage is the input portion of the shift register circuit, but the data that is input to the input portion of the shift register circuit can be weak. This is because there is also a case where data signal amplitude is decreased so that the data that is supplied from an external semiconductor device can be input to the input portion of the shift register circuit through a flexible printed circuit, wiring of an electro-optical device, or the like. Even in this case, because the pass gate of the D latch in the first stage that receives data directly is the N-type transistor, the data, although weak, can be correctly transmitted.

According to another application example, there is provided a shift register circuit including p (p is an integer that is 2 or greater) D latches, in which each of the p D latches includes a local input portion and a local output portion, in which the local output portion of the i-th (i is an integer from 1 to (p−1)) D latch and the local input portion of the (i+1)-th D latch are electrically connected to each other, in which each of the p D latches includes at least a pass gate, 2k (k is an integer that is 1 or greater) inverters, and a memory controller, in which a clock signal is supplied to the pass gate and the memory controller, in which the pass gate allows or disallows passing of data that is input to the local input portion, according to the clock signal, in which the memory controller causes the 2k inverters to function as buffer circuits or storage circuits, according to the clock signal, in which the p D latches in the odd-numbered stage are first type D latches and the p D latches in the even-numbered stage are second type D latches, in which the pass gate of the first type D latch and the pass gate of the second type D latch operate mutually complementarily, and in which the memory controller of the first type D latch and the memory controller of the second type D latch operate mutually complementarily.

With this configuration, the shift register circuit can be driven with the single phase clock. In other words, when the pass gate of the first type D latch allows the passing of the data, the pass gate of the second type D latch disallows the passing of the data, and when the memory controller of the first type D latch causes the 2k inverters to function as the buffer circuits, the memory controller of the second type D latch causes the 2k inverters to function as the storage circuits. Similarly, when the pass gate of the first type D latch disallows the passing of the data, the pass gate of the second type D latch allows the passing of the data, and when the memory controller of the first type D latch causes the 2k inverters to function as the storage circuits, the memory controller of the second type D latch causes the 2k inverters to function as the buffer circuits. Therefore, the shift register circuit can be caused to correctly operate, also with the single phase clock. The operation of the shift register circuit with the single clock can make the clock signal generation circuit unnecessary and decrease the system-wide circuit scale. Moreover, when the clock signals are two types, the shift register circuit can malfunction due to the phase difference between the two types of clock signals, but, because the single phase clock is possible with this configuration, a stable circuit operation can be realized without an occurrence of such a malfunction of the shift register circuit.

In the shift register circuit according to the application example, it is preferable that when the pass gate allows the passing of the data, memory controller cause the 2k inverters to function as the buffer circuits, and when the pass gate disallows the data, the memory controller cause the 2k inverters to function as the storage circuits.

With this configuration, when the clock signal is active, the pass gate, and the 2k inverters that function as the buffer circuits can transmit the data that is input to the local input portion, to the local output portion. On the other hand, when the clock signal is non-active, the pass gate disallows the inputting of the new data, and the 2k inverters, which function as the storage circuits, can retain the data that is input to the local input portion before the clock signal becomes non-active. Therefore, the D latch can be caused to correctly function, and the shift register circuit can be caused to correctly operate.

In the shift register circuit according to the application example, it is preferable that when the pass gate of the first type D latch allows the passing of the data that is input to the local input portion of the first type D latch, the pass gate of the second type D latch disallow the passing of the data that is input to the local input portion of the second type D latch, and when the pass gate of the first type D latch disallows the passing of the data that is input to the local input portion of the first type D latch, the pass gate of the second type D latch allow the passing of the data that is input to the local input portion of the second type D latch.

With this configuration, the first type D latch and the second type D latch can be mutually complementary. Therefore, the shift register circuit can be caused to correctly operate, with the single phase clock.

In the shift register circuit according to the application example, it is preferable that when the memory controller of the first type D latch causes the 2k inverters of the first type D latch to function as the buffer circuits, the memory controller of the second type D latch cause the 2k inverters of the second type D latch to function as the storage circuits, and when the memory controller of the first type D latch causes the 2k inverters of the first type D latch to function as the storage circuits, the memory controller of the second type D latch cause the 2k inverters of the second type D latch to function as the buffer circuits.

With this configuration, the first type D latch and the second type D latch can be mutually complementary. Therefore, the shift register circuit can be caused to correctly operate, with the single phase clock.

In the shift register circuit according to the application example, it is preferable that an ability of the pass gate of the first type D latch to allow the passing of the data be better than an ability of the pass gate of the second type D latch to allow the passing of the data.

With this configuration, because the ability of the pass gate of the first type D latch positioned in the odd-numbered stage to pass the data is better than the ability of the pass gate of the second type D latch positioned in the even-numbered stage to pass the data, in a case where the number of the D latches in the shift register circuit is odd, the number of the D latches, the pass gate of which has the better ability to pass the data, can be increased. In addition, the local input portion of the D latch in the first stage is the input portion of the shift register circuit, but the data that is input to the input portion of the shift register circuit may weak. This is because there is also a case where data signal amplitude is decreased so that the data that is supplied from an external semiconductor device can be input to the input portion of the shift register circuit through a flexible printed circuit, wiring of an electro-optical device, or the like. Even in this case, because the ability of the pass gate of the D latch in the first stage directly receiving data to pass the data is better, the data, although weak, can be correctly transmitted.

According to still another application example, there is provided an electro-optical device including any one of the application examples described above.

With this configuration, the electro-optical device can be realized that is small in a system-wide circuit scale. Moreover, the electro-optical device can be realized in which the display defect due to the malfunction of the shift register circuit is reduced. In addition, because the clock signal generation circuit is unnecessary, although a method of selecting every two scan lines, which is disclosed in JP-A-2012-49645, is employed, an occurrence of a vertical band that divides an image display region horizontally can be suppressed. In other words, the electro-optical device can be realized in which a high-grade image display is performed.

According to still another application example, there is provided an electronic apparatus including the electro-optical device according to any one of the application examples described above.

With this configuration, the electronic apparatus can be realized that is small in the system-wide circuit scale. Moreover, the electronic apparatus can be realized in which the display defect due to the malfunction of the shift register circuit is reduced. In addition, because the clock signal generation circuit is unnecessary, although the method of selecting every two scan lines, which is disclosed in JP-A-2012-49645, is employed, the occurrence of the vertical band that divides the image display region horizontally can be suppressed. In other words, the electro-optical device can be realized in which the high-grade image display is performed.

### BRIEF DESCRIPTION OF THE DRAWINGS

The invention will be described with reference to the accompanying drawings, wherein like numbers reference like elements.

FIGS. 1A and 1B are views, each illustrating a shift register circuit according to a first embodiment.

FIGS. 2A and 2B are views, each illustrating a state of the shift register circuit in a first duration.

FIGS. 3A and 3B are views, each illustrating the state of the shift register circuit in a second duration.

FIGS. 4A and 4B are views, each illustrating the state of the shift register circuit in a third duration.

FIGS. 5A and 5B are views, each illustrating the state of the shift register circuit in a fourth duration.

FIGS. 6A and 6B are timing charts, each illustrating a shift register circuit according to the first embodiment.

FIG. 7 is a view illustrating one example of a layout of the shift register circuit according to the first embodiment.

FIG. 8 is a view illustrating one example of the layout of the shift register circuit according to the first embodiment.

FIG. 9 is a plan view diagrammatically illustrating a circuit block configuration of a liquid crystal device according to the first embodiment.

FIG. 10 is a view illustrating an electric potential change in a clock signal CLK.

FIG. 11 is a cross-sectional view diagrammatically illustrating the liquid crystal device.

FIG. 12 is a view illustrating an equivalent circuit representing an electric configuration of the liquid crystal device.

FIG. 13 is a plan view illustrating a configuration of a three-chip type projector as an electronic apparatus.

FIGS. 14A and 14B are views, each illustrating the shift register circuit according to a comparative example.

FIG. 15 is a plan view diagrammatically illustrating the circuit block configuration of the liquid crystal device according to the comparative example.

### DESCRIPTION OF EXEMPLARY EMBODIMENTS

Embodiments according to the invention are described below, referring to the drawings. Moreover, because layers and members in the following drawings are enlarged in such an extent that they are recognizable, their scales are different from those in the real world.

### First Embodiment

### Configuration of Shift Register Circuit

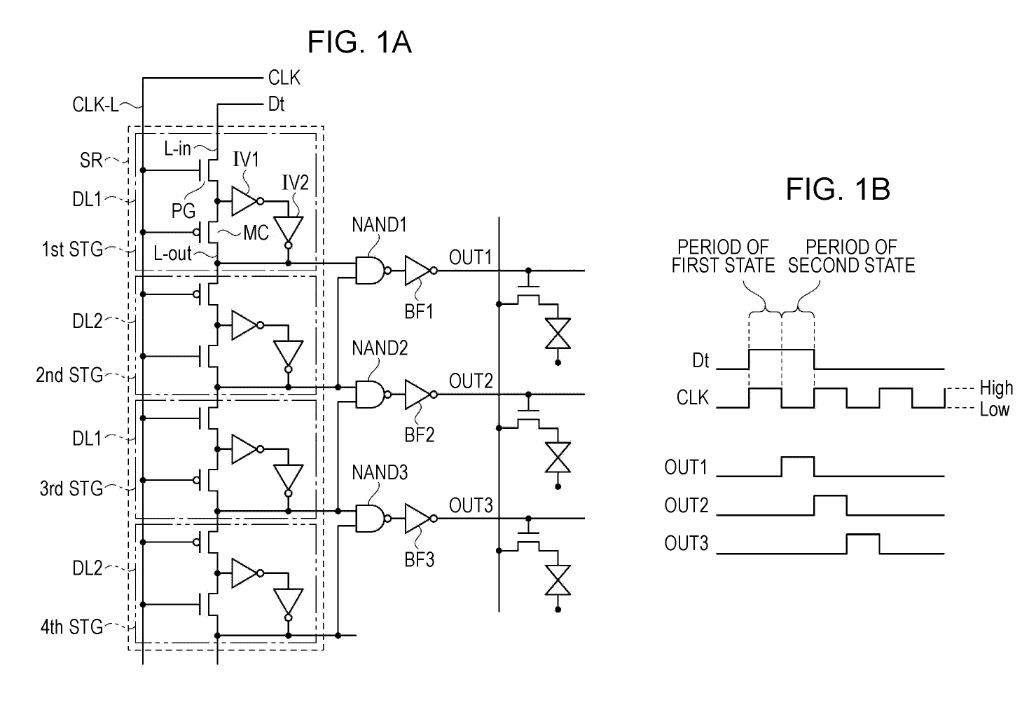

FIGS. 1A and 1B are views, each illustrating a shift register circuit according to a first embodiment. FIG. 1A is a circuit configuration diagram, and FIG. 1B is a timing chart of the shift register circuit. First, the shift register circuit according to the first embodiment is described, referring to FIGS. 1A and 1B.

A shift register circuit SR according to the first embodiment has p D latches (p is an integer that is two or greater) that are arranged in series and a clock line CLK-L. The D latch is a circuit element that makes a storage element controllable with a clock signal CLK, and each D latch includes a local input portion L-in, and a local output portion L-out. Specifically, the D latch is the circuit element in which in an active (CLK=1) duration, the supplied clock signal CLK outputs data in the local input portion L-in, as it is, to the local output portion L-out, and in a non-active (CLK=0) duration, the clock signal CLK retains the data in the local input portion L-in just before the clock signal CLK becomes non-active, and outputs the data to the local output portion L-out.

The p D latches, which makeup the shift register circuit SR, are electrically connected in series, and the p D latches in odd-numbered stages are first type D latches DL1, and the p D latch in even-numbered stages are second type D latches DL2. In FIG. 1A, the D latch 1st STG in the first stage and D latch 3rd STG in the third stage are the first type D latch DL1, and the D latch 2nd STG in the second stage and the D latch 4th STG in the fourth stage are the second type D latch DL2. The local output portion L-out of the i-th (i is an integer from 1 to (p−1)) D latch, and the local input portion L-in of the (i+1)-th D latch are electrically connected to each other. The local input portion L-in in the D latch 1st STG in the first stage is an input portion of the data Dt that is input to the shift register circuit SR.

Each of the p D latches includes at least a pass gate PG, 2k (k is an integer that is 1 or greater) inverters, and a memory controller MC, and each inverter includes an inverter input electrode and an inverter output electrode. The inverter output electrode of the n-th (n is an integer from 1 to (2k−1)) inverter is electrically connected to the inverter input electrode of the (n+1)-th inverter. The pass gate PG and the memory controller MC are made from a transistor. According to the first embodiment, when k=1, the first inverter IV1 and the second inverter IV2 are included in the D latch. The pass gate PG and the 2k inverters are electrically connected in series between the local input portion L-in and the local output portion L-out. That is, one of source and drain regions of the pass gate PG is the local input portion L-in, the other of the source and drain regions of the pass gate PG and the inverter input electrode of the first inverter IV1 are electrically connected to each other, the inverter output electrode of the first inverter IV1 and the inverter input electrode of the second inverter IV2 are electrically connected to each other, and the inverter output electrode of the second inverter IV2 is the local output portion L-out. According to the first embodiment, since k=2, the simple configuration like this is provided, but generally the 2k inverters are electrically connected in series to each other in this manner, and the 2k-th inverter output electrode is the local output portion L-out.

Within the D latch, one of the source and drain regions of the memory controller MC, the inverter input electrode of the first inverter IV1, and the other of the source and drain regions of the pass gate PG are electrically connected to each other, and the other of the source and drain regions of the memory controller MC and the inverter output electrode of the 2k-th inverter are electrically connected to each other. As a result, the other of the source and drain regions of the memory controller MC is the local output portion L-out, and the memory controller MC is electrically connected to the 2k inverters, in parallel, between the pass gate PG and the local output portion L-out.

A control electrode of the pass gate PG is a gate electrode, and the control electrode of the memory controller MC is the gate electrode as well. The control electrode of the pass gate PG and the control electrode of the memory controller MC is electrically connected to the clock line CLK-L, and operation of the pass gate PG and operation of the memory controller MC are also controlled with the clock signal CLK that is supplied to the clock line CLK-L. That is, the clock signal CLK is supplied to the pass gate PG and the memory controller MC through the clock line CLK-L. The pass gate PG allows or disallows passing of the data that is input to the local input portion L-in, according to the clock signal CLK. On the other hand, the memory controller MC causes the 2k inverters to function as buffer circuits or storage circuits, according to the clock signal CLK. The clock signal CLK, as illustrated in FIG. 1B, makes up its one period with a first state duration and a second state duration, and repeats with this period. Moreover, according to the first embodiment, electric potential of the clock line CLK-L is increased in the first state duration of the clock signal CLK (HIGH, and a first state), and the electric potential of the clock line CLK-L is decreased in the second state duration of the clock signal CLK (LOW, and a second state). In addition, a ratio of the first state duration to one period is referred to as a duty ratio, and according to the first embodiment, the duty ratio is 50%. That is, the duration in which the electric potential of the clock line CLK-L is HIGH, and the duration in which the electric potential of the clock line CLK-L is LOW are approximately equal to each other.

As described above, the p D latches in the odd-numbered stage is the first type D latch DL1, but the pass gate PG of the first type D latch DL1 is made from a first conductivity type transistor, and the memory controller MC of the first type D latch DL1 is made from a second conductivity type transistor that is different from the first conductivity type. Conversely, the p D latches in the even-numbered stage is the second type D latch DL2, the pass gate PG of the second type D latch DL2 is made from the second conductivity type transistor, and the memory controller MC of the second type D latch DL2 is made from the first conductivity type transistor. As a result, in the second type D latch DL2 as well as in the first type D latch DL1, when the pass gate PG allows the passing of the data, the memory controller MC causes the 2k inverters to function as the buffer circuits, and the pass gate PG disallows the passing of the data, the memory controller MC causes the 2k inverters to function as the storage circuits. In other words, in the second type D latch DL2 as well as in the first type D latch DL1, when the clock signal CLK is active, the pass gate PG, and the 2k inverters, which function as the buffer circuits, transmit the data, which is input to the local input portion L-in, to the local output portion L-out. On the other hand, in the second type D latch DL2 as well as in the first type D latch DL1, when the clock signal CLK is non-active, the pass gate PG disallows the inputting of the new data, and the 2k inverters, which function as the storage circuits, retain the data that is input to the local input portion L-in before the clock signal CLK is non-active. That is, the first type D latch DL1 and the second type D latch DL2 correctly function as the D latches, and the shift register circuit SR, which is made from these, correctly operates.

Moreover, as a result of the configuration described above, the pass gate PG of the first type D latch DL1 and the pass gate PG of the second type D latch DL2 mutually perform complementary operation, and the memory controller MC of the first type D latch DL1 and the memory controller MC of the second type D latch DL2 mutually perform complementary operation. By the fact that the pass gates PG are mutually complementary, it is meant that when the pass gate PG of the first type D latch DL1 allows the passing of the data that is input to the local input portion L-in of the first type D latch DL1, the pass gate PG of the second type D latch DL2 disallows the passing of the data that is input to the local input portion L-in of the second type D latch DL2, and when the pass gate PG of the first type D latch DL1 disallows the passing of the data that is input to the local input portion L-in of the first type D latch DL1, the pass gate PG of the second type D latch DL2 allows the passing of the data that is input to the local input portion L-in of the second type D latch DL2. In addition, by the fact that the memory controller MC are mutually complementary, it is meant that when the memory controller MC of the first type D latch DL1 causes the 2k inverters of the first type D latch DL1 to function as the buffer circuits, the memory controller MC of the second type D latch DL2 causes the 2k inverters of the second type D latch DL2 to function as the storage circuits, and when the memory controller MC of the first type D latch DL1 causes the 2k inverters of the first type D latch DL1 to function as the storage circuits, the memory controller MC of the second type D latch DL2 causes the 2k inverters of the second type D latch DL2 to function as the buffer circuits. As a result of doing this, the first type D latch DL1 and the second type D latch DL2 are mutually complementary. Specifically, the first state (HIGH) of the clock signal CLK is equivalent to being active in the first type D latch DL1 and is equivalent to being non-active in the second type D latch DL2. Conversely, the second state (LOW) of the clock signal CLK is equivalent to being non-active in the first type D latch DL1 and is equivalent to being active in the second type D latch DL2. As a result, in a duration of time when the first type D latch DL1 transmits the data in the local input portion L-in of the first type D latch DL1 to the local output portion L-out of the first type D latch DL1, the second type D latch DL2 retains the data that is input to the local input portion L-in of the second type D latch DL2 at the previous clock signal CLK and outputs the data to the local output portion L-out of the second type D latch DL2. Similarly, in a duration of time when the first type D latch DL1 retains the data that is input to the local input portion L-in of the first type D latch DL1 at previous clock signal CLK and outputs the data to the local output portion L-out of the first type D latch DL1, the second type D latch DL2 transmits the data in the local input portion L-in of the second type D latch DL2 to the data to the local output portion L-out of the second type D latch DL2. In this manner, because a single phase clock complementarily functions with the first type D latch DL1 and the second type D latch DL2, the shift register circuit SR is caused to correctly operate with the single phase clock.

According to the first embodiment, the first conductivity type transistor is an N-type transistor, and the second conductivity type transistor is a P-type transistor. This is because the N-type transistor has higher conductance than the P-type transistor. When a comparison is made between the pass gate PG and memory controller MC, the pass gate PG has higher conductance, because whereas the pass gate PG allows the passing of the data in an ON state, the memory controller MC only retains the data that is present in a previous clock duration, in an ON state. When the pass gate PG of the first type D latch DL1 positioned in the odd-numbered stage is configured from the N-type transistor, an ability of the pass gate PG of the first type D latch DL1 to allow the passing of the data is better than an ability of the pass gate PG of the second type D latch DL2 to allow the passing of the data. In other words, the ability of the pass gate PG of the first type D latch DL1 positioned in the odd-numbered stage to allow the passing of the data is better than the ability of the pass gate PG of the second type D latch DL2 positioned in the even-numbered stage to allow the passing of the data. Therefore, in a case where the number of the D latches in the shift register circuit SR is odd, the number of the N-type transistors that make up the pass gate PG can be increased more greatly than the number of the P-type transistors that make up the pass gate PG. In other words, the number of the first type D latches DL1 with the better ability to allow the passing of the data can be more than the number of the second type D latch DL2, and a normal operation probability of the shift register circuit SR is increased that much.

Furthermore, there is also a case where data Dt that is input to the input portion of the shift register circuit SR is weak in signal strength. This is because there is also a case where data signal amplitude is decreased so that the data Dt that is supplied from an external semiconductor device and is input to the shift register circuit SR can be input to the input portion of the shift register circuit SR through a flexible printed circuit, wiring of an electro-optical device, or the like. Even in this case, weak data can also be correctly transmitted because the pass gate PG of the D latch in the first stage, which directly receives the data, is the N-type transistor, and the D latch in the first stage is the D latch with the better ability to allow the passing of the data.

Moreover, the electrical connecting of a terminal 1 and a terminal 2 includes the connecting of the terminal 1 and the terminal 2 through a resistance element and a switching element, in addition to the direct connecting of the terminal 1 and the terminal 2 through wiring. That is, even though the terminal 1 and the terminal 2 are somewhat different in electric potential, in a case where they provide the same meaning in the circuit, they are meant to be connected to each other. For example, in FIG. 1A, the local input portion L-in of the first type D latch DL1 and the inverter input electrode of the first inverter IV1 are electrically connected to each other. The pass gate PG is actually interposed between the local input portion L-in and the inverter input electrode of the first inverter IV1, but in a case where the pass gate PG is in an ON state, judging from the circuital meaning that the electric potential of the inverter input electrode of the first inverter IV1 is almost equivalent to the electric potential of the local input portion L-in, it can be said that the local input portion L-in of the first type D latch DL1 and the inverter input electrode of the first inverter IV1 are electrically connected to each other.

In addition, according to the first embodiment, the first state of the clock signal CLK is defined as high electric potential (HIGH) and the second state is defined as low electric potential (LOW), but conversely, the first state may be defined as low electric potential (LOW) and the second state may be defined as high electric potential (HIGH). Besides, according to the first embodiment, the first conductivity type transistor is defined as the N-type transistor and the second conductivity type transistor is defined as the P-type transistor, but the first conductivity type transistor may be defined as the P-type transistor and the second conductivity type transistor may be defined as the N-type transistor.

### Operation of Shift Register Circuit

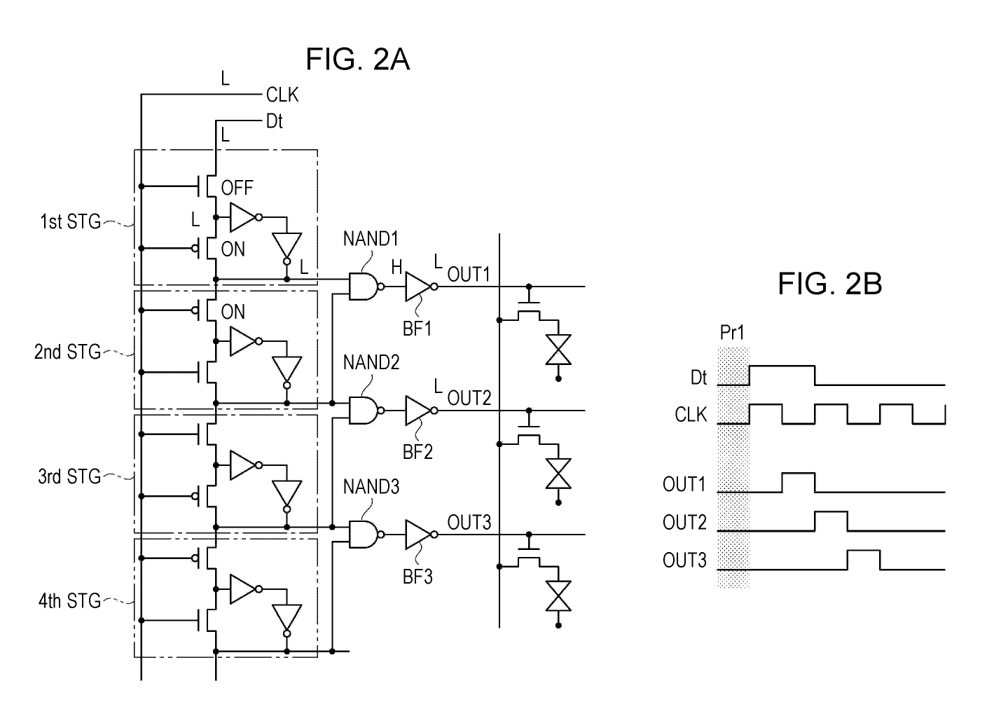

FIGS. 2A to 5B illustrate operation of the shift register circuit according to the first embodiment. FIGS. 2A, 3A, 4A, and 5A are circuit configuration diagrams, and FIGS. 2B, 3B, 4B, and 5B are timing charts of the shift register circuit. Next, an operational situation of the shift register circuit SR according to the first embodiment is described, referring to FIGS. 2A to 5B.

FIGS. 2A and 2B are views, each illustrating a state of the shift register circuit SR in a first duration Pr1 of the clock signal CLK. In this duration, the clock signal CLK is LOW, and the LOW data Dt is input to the input portion (the local input portion L-in in the D latch 1st STG in the first stage) to the shift register circuit SR. The pass gate PG in the D latch 1st STG in the first stage is in an OFF state. The memory controller MC in the D latch 1st STG in the first stage is in an ON state, and thus the 2k inverters operate as the storage circuit. The storage circuit retains the LOW signal and outputs the LOW signal to the local output portion L-out in the D latch 1st STG in the first stage. The local output portion L-out in the D latch 1st STG in the first stage is electrically connected to a first input of a NAND circuit NAND1 in the first stage. Because the first input of the NAND circuit NAND1 in the first stage is LOW, an output of this circuit is HIGH. An output of the NAND circuit NAND 1 in the first stage is electrically connected to an input of an output buffer circuit BF1 in the first stage. Because the input of the output buffer circuit BF1 in the first stage is HIGH, an output of this circuit is LOW.

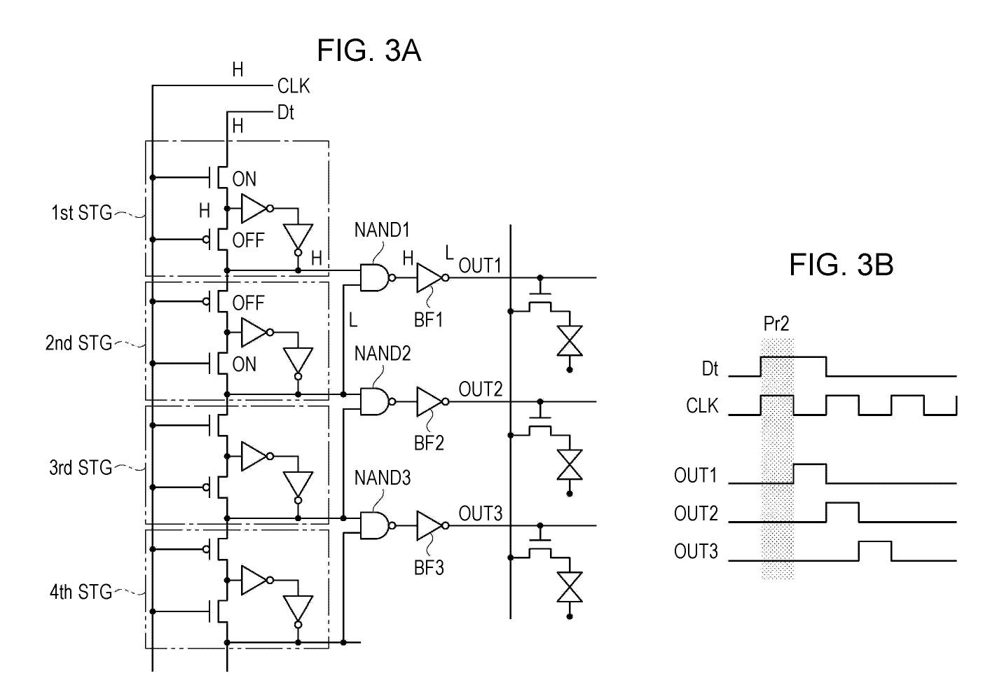

FIGS. 3A and 3B are views, each illustrating a state of the shift register circuit SR in a second duration Pr2 of the clock signal CLK. In this duration, the clock signal CLK is HIGH, and the HIGH data Dt is input to the input portion (the local input portion L-in in the D latch 1st STG in the first stage) to the shift register circuit SR. The pass gate PG in the D latch 1st STG in the first stage is in an ON state, and the memory controller MC in D latch 1st STG in the first stage is in an OFF state, and thus the 2k inverters operate as the buffer circuit. Because of this, the HIGH data that is input to the local input portion L-in in the D latch 1st STG in the first stage, as it is, is output to local output portion L-out in the D latch 1st STG in the first stage. As a result, a first input of the NAND circuit NAND1 in the first stage is HIGH.

The HIGH Data is input to the local input portion L-in in the D latch 2nd STG in the second stage, but the pass gate PG in the D latch 2nd STG in the second stage is in an OFF state and thus disallows the passing of this. The memory controller MC in the D latch 2nd STG in the second stage is in an ON state, and thus the 2k inverters operate as the storage circuit. The storage circuit retains the LOW signal that is input in the first duration Pr1 and outputs the LOW signal to the local output portion L-out in the D latch 2nd STG in the second stage. The local output portion L-out in the D latch 2nd STG in the second stage is electrically connected to a second input of the NAND circuit NAND1 in the first stage and a first input of a NAND circuit MAND2 in a second stage. Because the second input of the NAND circuit NAND 1 in the first stage and the first input of the NAND circuit NAND2 in the second stage are LOW, the output of the NAND circuit NAND 1 in the first stage and the output of the NAND circuit NAND2 in the second stage are HIGH. As a result, an output OUT1 of the output buffer circuit BF1 in the first stage and an output OUT2 of an output buffer circuit BF2 in the second stage are LOW.

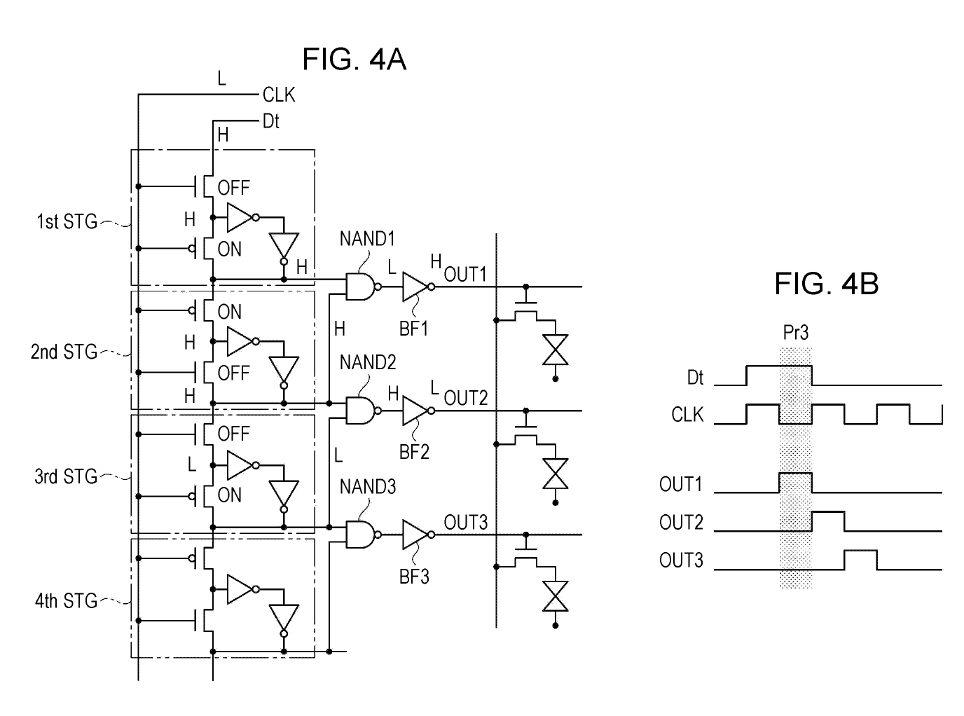

FIGS. 4A and 4B are views, each illustrating a state of the shift register circuit SR in a third duration Pr3 of the clock signal CLK. In this duration, the clock signal CLK is LOW, and the HIGH data Dt is input to the input portion (the local input portion L-in in the D latch 1st STG in the first stage) to the shift register circuit SR. The pass gate PG of the D latch 1st STG in the first stage is in an OFF state and thus disallows the passing of this. The memory controller MC in the D latch 1st STG in the first stage is in an ON state, and thus the 2k inverters operate as the storage circuit. The storage circuit retains the HIGH signal that is input in the second duration Pr2 and outputs the HIGH signal to the local output portion L-out in the D latch 1st STG in the first stage.

The HIGH Data is input to the local input portion L-in in the D latch 2nd STG in the second stage. The pass gate PG in the D latch 2nd STG in the second stage is in an ON state. Moreover, the memory controller MC in the D latch 2nd STG in the second stage is in an OFF state, and thus the 2k inverters operate as the buffer circuit. Because of this, the HIGH data that is input to the local input portion L-in in the D latch 2nd STG in the second stage, as it is, is output to local output portion L-out in the D latch 2nd STG in the second stage. Because of this, the second input of the NAND circuit NAND1 in the first stage and the first input of the NAND circuit NAND2 in the second stage are LOW. Because the first input of the NAND circuit NAND1 in the first stage and the second input of the NAND circuit NAND 1 in the first stage are HIGH, the output of the NAND circuit NAND1 in the first stage is LOW and the output OUT1 of the output buffer circuit BF1 in the first stage is HIGH.

The HIGH data is input to the local input portion L-in in the D latch 3rd STG in the third stage, but the pass gate PG in the D latch 3rd STG in the third stage is in an OFF state and thus disallows the passing of this. The memory controller MC in the D latch 3rd STG in the third stage is in an ON state, and thus the 2k inverters operate as the storage circuit. The storage circuit retains the LOW signal that is input in the second duration Pr2 and outputs the LOW signal to the local output portion L-out in the D latch 3rd STG in the third stage. The D latch 3rd STG of the third stage is electrically connected to the second input of the NAND circuit NAND2 in the second stage and the first input of the NAND circuit NAND3 in the third stage. Because the second input of the NAND circuit NAND2 in the second stage and the first input of the NAND circuit NAND3 in the third stage are LOW, the output of the NAND circuit NAND2 in the second stage and the output of the NAND circuit NAND3 in the third stage are HIGH. As a result, the output OUT2 of the output buffer circuit BF2 in the second stage and an output OUT3 of an output buffer circuit BF3 in the third stage are LOW.

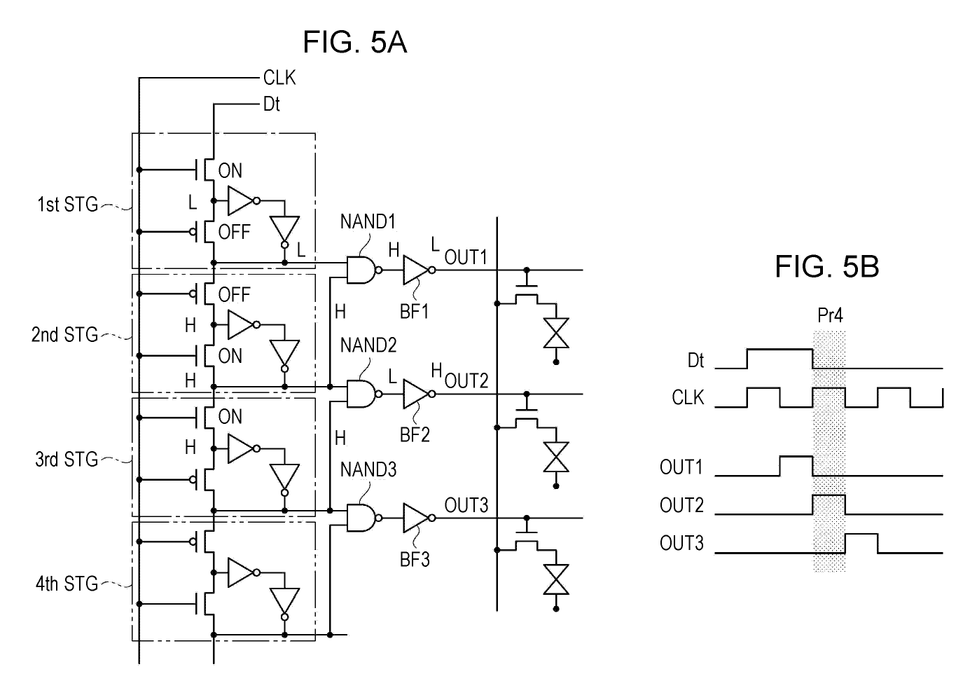

FIGS. 5A and 5B are views, each illustrating a state of the shift register circuit SR in a fourth duration Pr4 of the clock signal CLK. In this duration, the clock signal CLK is HIGH, and the LOW data Dt is input to the input portion (the local input portion L-in in the D latch 1st STG in the first stage) to the shift register circuit SR. The pass gate PG in the D latch 1st STG in the first stage is in an ON state, and the memory controller MC in D latch 1st STG in the first stage is in an OFF state, and thus the 2k inverters operate as the buffer circuit. Because of this, the LOW data that is input to the local input portion L-in in the D latch 1st STG in the first stage, as it is, is output to local output portion L-out in the D latch 1st STG in the first stage. As a result, the first input of the NAND circuit NAND 1 in the first stage is LOW, and the output OUT 1 of an output buffer circuit BF 1 in the first stage is LOW.

The LOW Data is input to the local input portion L-in in the D latch 2nd STG in the second stage, but the pass gate PG in the D latch 2nd STG in the second stage is in an OFF state and thus disallows the passing of this. The memory controller MC in the D latch 2nd STG in the second stage is in an ON state, and thus the 2k inverters operate as the storage circuit. The storage circuit retains the HIGH signal that is input in the third duration Pr3 and outputs the HIGH signal to the local output portion L-out in the D latch 2nd STG in the second stage. That is, the second input of the NAND circuit NAND1 in the first stage, and the first input of the NAND circuit NAND2 in the second stage are HIGH.

The HIGH Data is input to the local input portion L-in in the D latch 3rd STG in the third stage. The pass gate PG in the D latch 3rd STG in the third stage is in an ON state, and the memory controller MC in D latch 3rd STG in the third stage is in an OFF state, and thus the 2k inverters operate as the buffer circuit. Because of this, the HIGH data that is input to the local input portion L-in in the D latch 3rd STG in the third stage, as it is, is output to local output portion L-out in the D latch 3rd STG in the third stage. Because of this, the second input of the NAND circuit NAND2 in the second stage, and the first input of the NAND circuit NAND3 in the third stage are HIGH. Because the first input of the NAND circuit NAND2 in the second stage and the second input are HIGH, the output of the NAND circuit NAND2 in the second stage is LOW and the output OUT2 of the output buffer circuit BF2 in the second stage is HIGH.

The HIGH Data is input to the local input portion L-in in the D latch 4th STG in the fourth stage, but the pass gate PG in the D latch 4th STG in the fourth stage is in an OFF state and thus disallows the passing of this. The memory controller MC in the D latch 4th STG in the fourth stage is in an ON state, and thus the 2k inverters operate as the storage circuit. The storage circuit retains the LOW signal that is input in the third duration Pr3 and outputs the LOW signal to the local output portion L-out in the D latch 4rd STG in the fourth stage. The D latch 4th STG in the fourth stage is electrically connected to the second input of the NAND circuit NAND3 in the third stage and the first input of the NAND circuit in the fourth stage. Because the second input of the NAND circuit NAND3 in the third stage and the first input of the NAND circuit in the fourth stage are LOW, the output of the NAND circuit NAND3 in the third stage and the output of the NAND circuit NAND3 in the third stage are HIGH. As a result, the output OUT3 of the output buffer circuit BF3 in the third stage and the output of the output buffer circuit in the fourth stage are LOW.

Thereafter, the same operations are repeated, the data Dt that is input to the input portion of the shift register circuit SR is transmitted by the latch in one stage every half period of the clock signal CLK.

### Duty Ratio

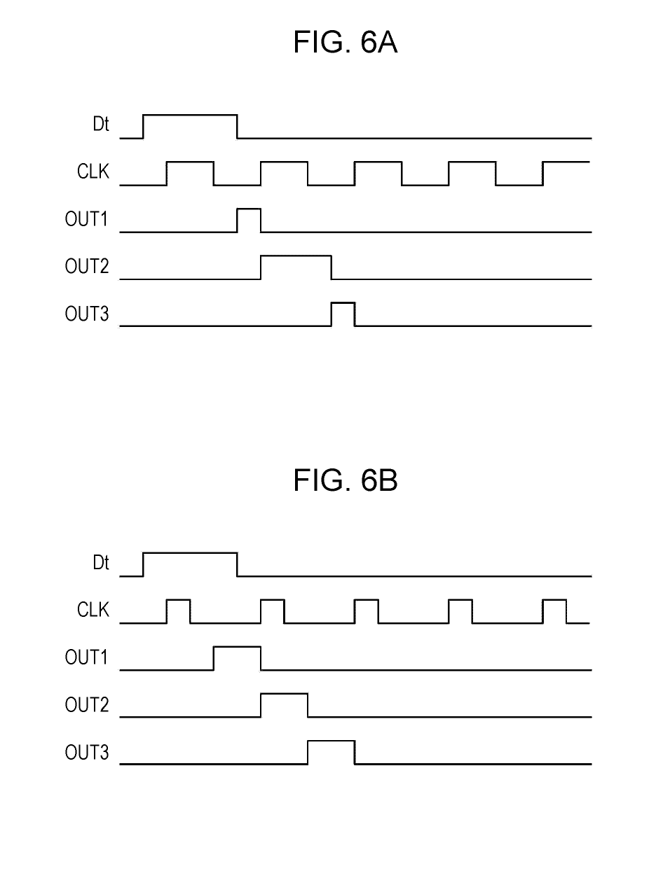

FIGS. 6A and 6B are timing charts, each illustrating the shift register circuit according to the first embodiment. Next, a method of exactly operating the shift register circuit SR according to the first embodiment is described, referring to FIGS. 6A and 6B.

The operation of the shift register circuit SR is as described above, but the preceding description is for a situation in an ideal system. FIG. 6A illustrates a timing chart that can occur when there is a deviation from the ideal system, and FIG. 6B is a timing chart illustrating a method of compensating for the occurring deviation from the ideal system. In a real system, because the N-type transistor and the P-type transistor are different in conductance from each other, ON resistances of both of transistors are different, and for this reason, there is a likelihood that a situation occurs in which the output from the output buffer circuit deviates from the ideal system (FIG. 5B and others). Specifically, as illustrated in FIG. 6A, in a case where the duty ratio of the clock signal CLK is 50%, there is a concern that the duration (the selection duration) of HIGH that is output from the output buffer circuit in the odd-numbered stage is shorter than the ideal system, and the duration (the selection duration) of HIGH that is output from the output buffer circuit in the even-numbered stage is longer than the ideal system. This occurs in a case where the ON resistance of the pass gate PG of a second type D latch DL2 can be greater than the ON resistance of the pass gate PG of the first type D latch DL1. This occurs because a signal delay in the pass gate PG of the second type D latch DL2 is greater than a signal delay in the pass gate PG of the first type D latch DL1.

This concern, as illustrated in FIG. 6B, is solved by shortening the duration (the first state duration of the clock signal CLK) in which the first type D latch DL1 is made active, much more than the half period of the clock signal, and by lengthening the period (the second state duration of the clock signal CLK) in which the second type D latch DL2 is made active, much more than the half period of the clock signal. Specifically, in one period of the clock signal, according to a difference between the ON resistances, the duration in which the P-type transistor, which makes up the pass gate PG, is made to be in an ON state is lengthened much more than the duration in which the N-type transistor, which makes up the pass gate PG, is made to be in an ON state. When this is done, it is possible to almost equalize the selection duration in the output buffer circuit in the odd-numbered stage and the selection duration in the output buffer circuit in the even-numbered stage, in such a manner as to be the same as the ideal system.

### Layout

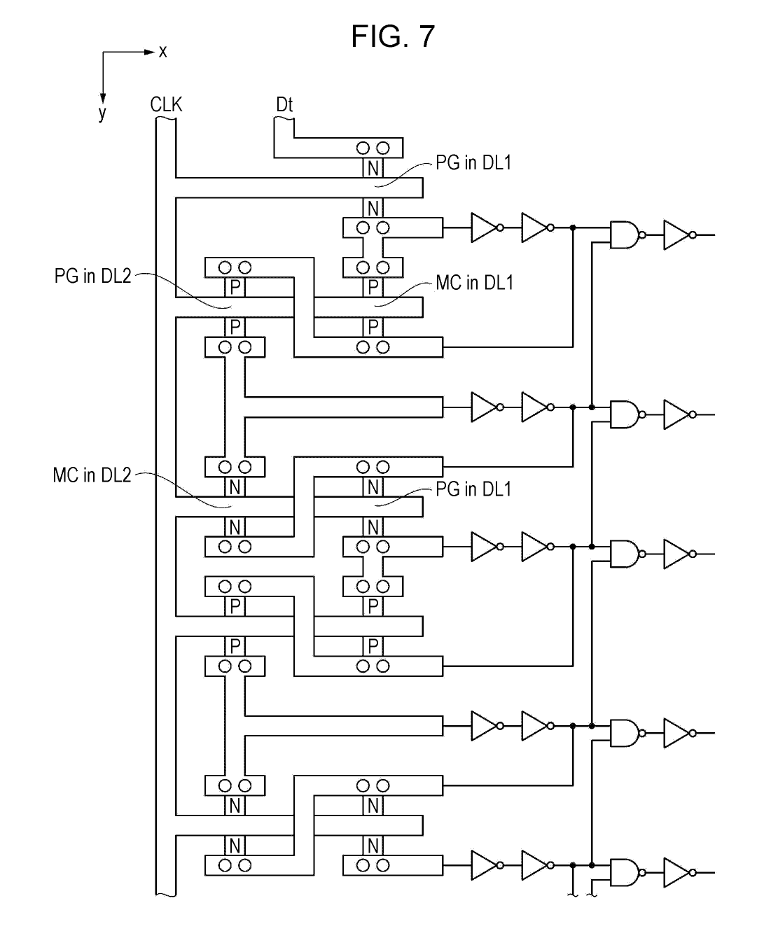

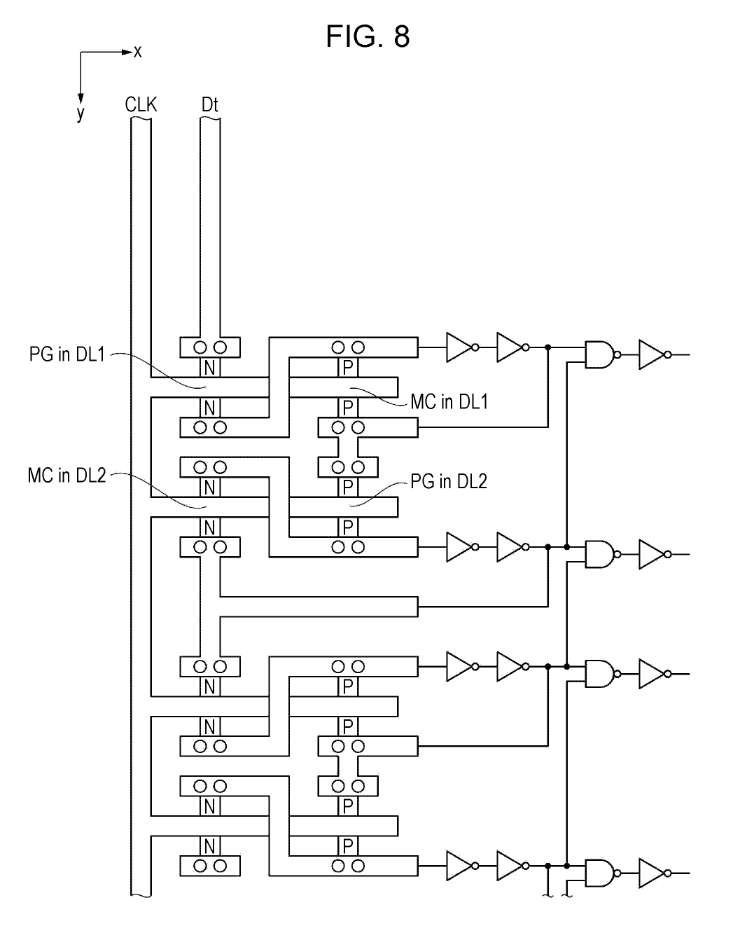

FIG. 7 and FIG. 8 are views, each illustrating one example of a layout of the transistor in the shift register circuit according to the first embodiment. Next, the layout of the transistor in the shift register circuit SR according to the first embodiment is described referring to FIG. 7 and FIG. 8.

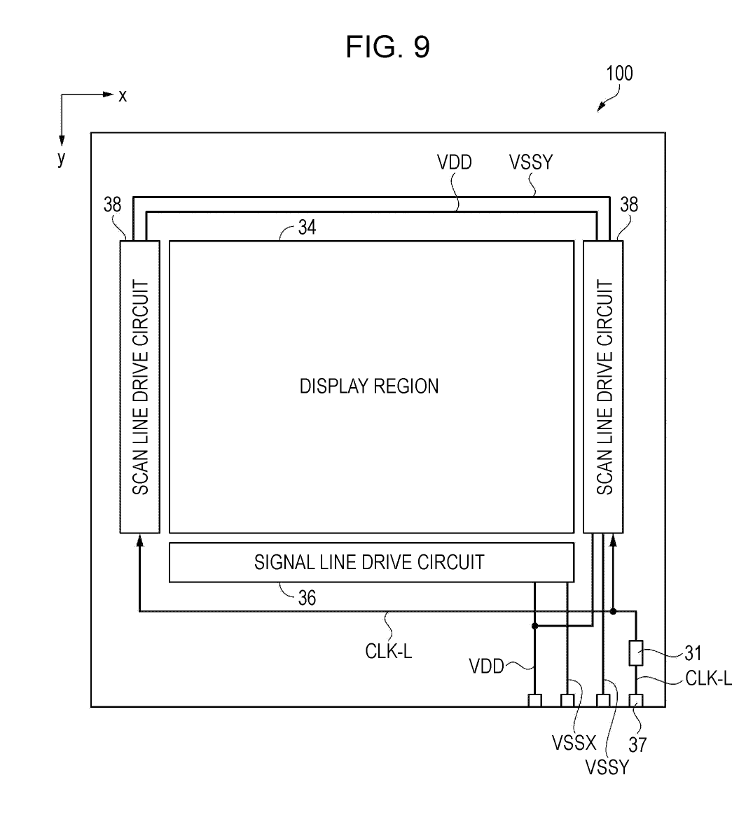

In addition to the 2k inverters, the D latch includes the N-type transistor and the P-type transistor. In a case where the transistor is a thin film transistor, and thus a well formation is unnecessary, the N-type transistor and the P-type transistor can be arranged relatively freely. Therefore, as illustrated in FIG. 7, the same conductivity type transistors of the adjacent D latches may be aligned in a first direction (in the X direction and in the row direction according to the first embodiment). In FIG. 7, the memory controller MC of the first type D latch DL1 and the pass gate PG of the second type D latch DL2 are aligned to be arranged in the first direction, and similarly, the memory controller MC of the second type D latch DL2 and the pass gate PG of the first type D latch DL1 are aligned to be arranged in the first direction. When this is done, a formation region of the N-type transistor can be narrowed much more than a formation region of the P-type transistor in relation to a second direction, and a length of the second direction of the shift register circuit SR can be decreased. When the shift register circuit SR is adapted to a scan line drive circuit 38 (refer to FIG. 9) of an electro-optical device (refer to FIG. 9), a support for the narrow pixel pitch is possible and the high-definition electro-optical device can be realized. In addition, since the two transistors aligned in the first direction are the same conductivity type, the widths of the gate electrodes can be equal, and the simplification of a wiring pattern of the gate electrode is made possible. At this point, the second direction intersects the first direction, and according to the first embodiment, is the Y direction that crosses at a right angle to the X direction. This direction is defined as a column direction. Moreover, a channel formation region of the N-type transistor is 3 μm in length and 3 μm in width, and a channel formation region of the P-type transistor is 5 μm in length and 8 μm in width.

Therefore, as illustrated in FIG. 8, the same conductivity type transistors of the adjacent D latches may be aligned in the second direction (in the Y direction and in the column direction according to the first embodiment). In FIG. 8, the memory controller MC of the first type D latch DL1 and the pass gate PG of the second type D latch DL2 are aligned to be arranged in the second direction, and similarly, the memory controller MC of the second type D latch DL2 and the pass gate PG of the first type D latch DL1 are aligned to be arranged in the second direction. When this is done, the formation region of the N-type transistor can be narrowed much more than the formation region of the P-type transistor in relation to the second direction, and the length of the first direction of the shift register circuit SR can be decreased. When the shift register circuit SR is adapted to the scan line drive circuit 38 of the electro-optical device, a narrow frame-shaped electro-optical device, which is the electro-optical device in which the outer peripheral region other than a display region 34 (refer to FIG. 9) is narrow, can be realized.

### Comparative Example of Shift Register Circuit

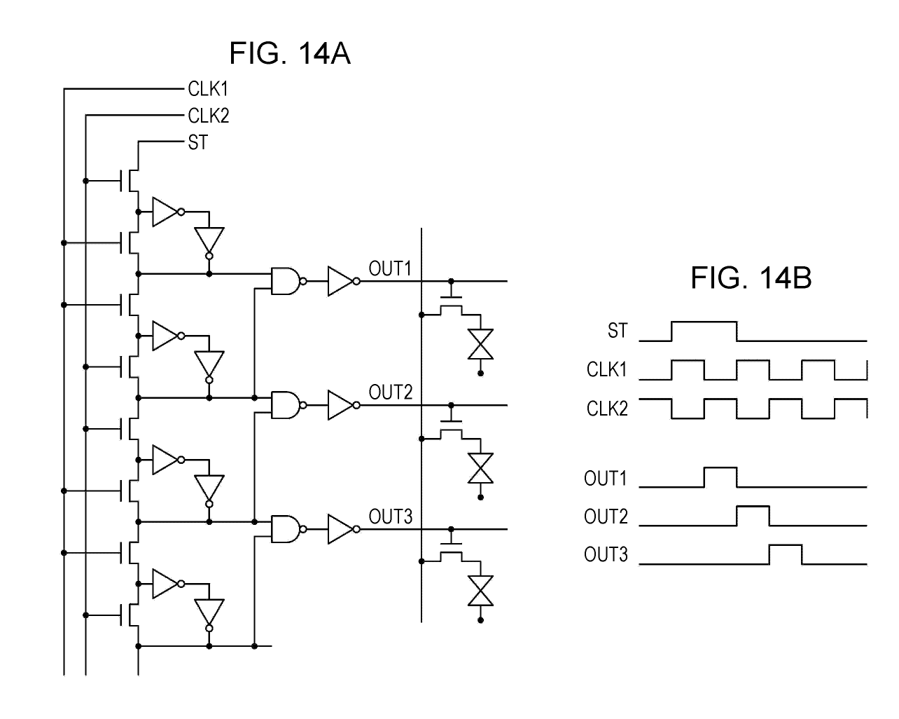

FIGS. 14A and 14B each illustrate a shift register circuit according to a comparative example. FIG. 14A is a circuit configuration diagram, and FIG. 14B is a timing chart of the shift register circuit. Next, effects of the shift register circuit SR according to the first embodiment are described, referring to the comparative examples in FIGS. 14A and 14B.

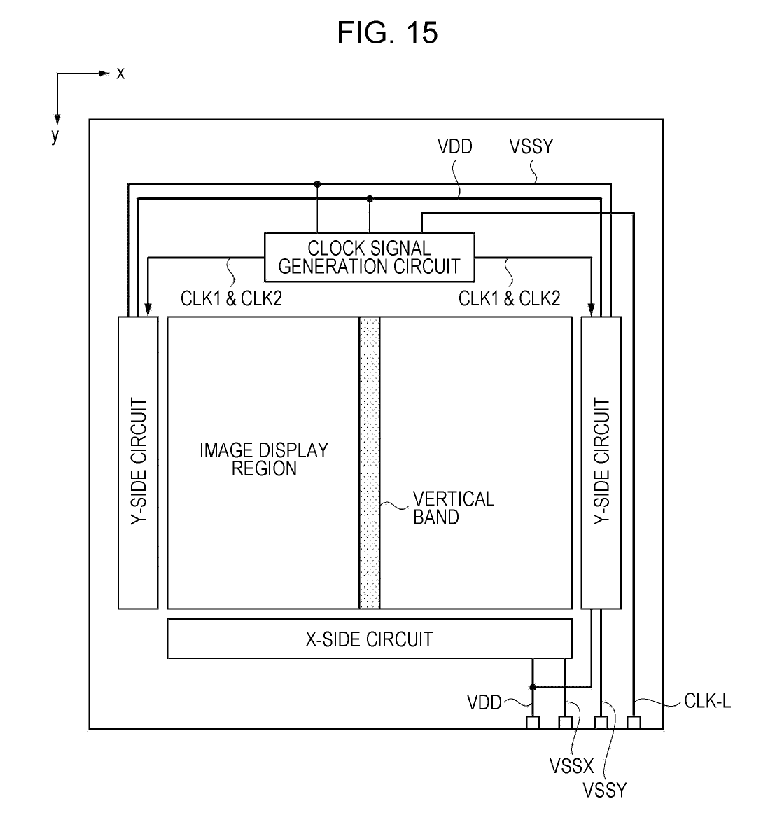

In the comparative example illustrated in FIG. 14A, the d latches in the odd-numbered stage and in the even-numbered stage that make up the shift register circuit have the same circuit configuration. That is, the pass gate and the memory controller are made from the same conductivity type transistors. Because of this, as illustrated in FIG. 14A, the first clock signal CLK1 and the second clock signal CLK2 has to be supplied to the shift register circuit. The first clock signal CLK1 and the second clock signal CLK2, as illustrated in FIG. 14B, are mutually complementary and when one of them is in the first state, the other is in the second state. In such a comparative example, a clock signal generation circuit (refer to FIG. 15) that generates the first clock signal CLK1 and the second clock signal CLK2 is indispensable and a system (for example, a liquid crystal device)-wide circuit scale has no choice but to be increased. In addition, the shift register circuit malfunctions when a phase difference out of a tolerance range is present in the first clock signal CLK1 and the second clock signal CLK2.

In contrast, the shift register circuit SR according to the first embodiment is driven with a single phase clock. That is, there is no need to prepare for various bi-phase clock signals of the comparative example. Therefore, the clock signal generation circuitry is unnecessary and thus the system-wide circuit scale can be decreased. Moreover, since clock signal CLK is in one phase, the malfunction of the shift register circuit SR resulting from the phase difference between the bi-phase clock signals cannot occur.

### Circuit Block Configuration of Electro-Optical Device

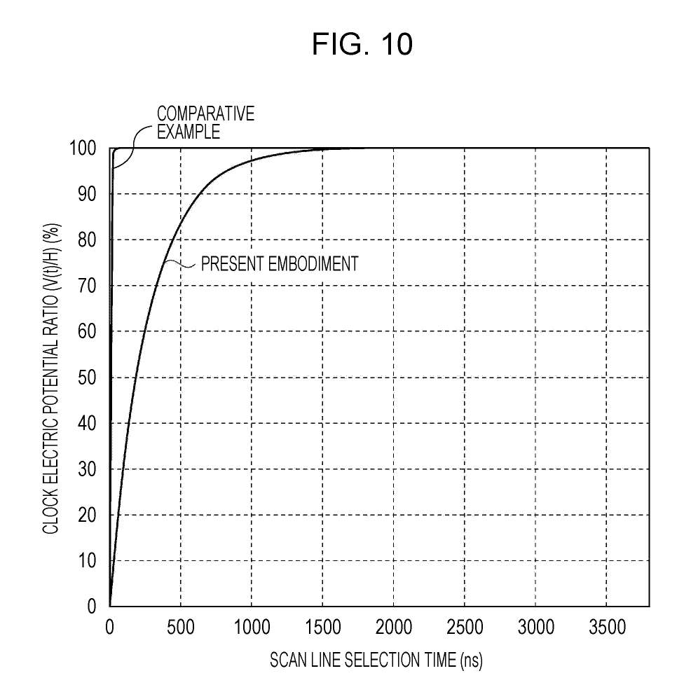

FIG. 9 is a plan view diagrammatically illustrating the circuit block configuration of the liquid crystal device according to the first embodiment. FIG. 10 is a view illustrating an electric potential change in the clock signal CLK. The circuit block configuration of the electro-optical device is described referring to FIGS. 9 and 10.

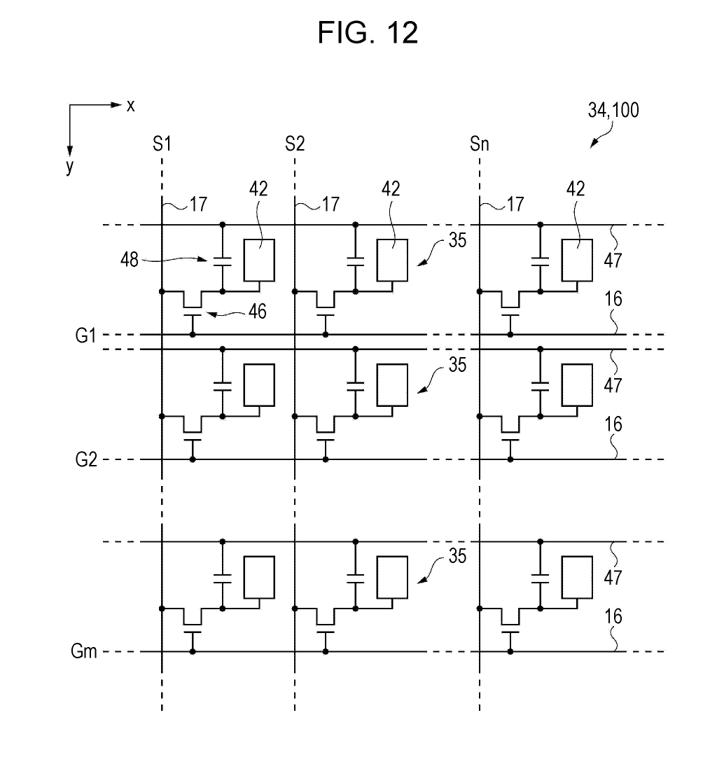

A liquid crystal device 100 is an electro-optical device, an active matrix type that uses the thin film transistor (referred to as TFT element 46 and refer to FIG. 12) as the switching element of a pixel 35 (refer to FIG. 12). As illustrated in FIG. 9, the liquid crystal device 100 includes at least the display region 34, a signal line drive circuit 36, the scan line drive circuit 38 and an external connection terminal 37.

The pixel 35 is provided, in the shape of a matrix state, within display region 34. The pixel 35 is a region which is defined by the scan line 16 (refer to FIG. 12) and the signal line 17 (refer to FIG. 12) that intersects each other, and the one pixel 35 is a region from one scan line 16 to another adjacent scan line 16 and additionally, a region from one signal line 17 to another adjacent signal line 17. The signal line drive circuit 36 and the scan line drive circuit 38 are formed outside of the display region 34. The scan line drive circuit 38 is formed, along each of the two sides adjacent to the display region 34, and includes the shift register circuit SR described above.

A positive power source VDD, a negative power source VSSX for the signal line drive circuit, and others are wired to the signal line drive circuit 36 from the external connection terminal 37. Furthermore, the positive power source VDD, a negative power source VSSY for the scan line drive circuit, the clock line CLK-L, and shift register input wiring (not illustrated) are wired to the scan line drive circuit 38 from the external connection terminal 37. The shift register input wiring connects to the input portion of the shift register circuit SR and supplies the data Dt to the shift register circuit SR. Moreover, in FIG. 9, all wiring and all external connection terminals are not illustrated and only the representative wiring from these is illustrated for the purpose of an easy-to-understand description.

The clock line CLK-L is electrically connected to the shift register circuit SR arranged in the scan line drive circuit 38, but a protection resistance 31 is arranged between the external connection terminal 37 of the clock line CLK-L and the shift register circuit SR. This is because a resistance value of the clock line CLK-L is increased to a certain extent, and this causes a moderate delay in the clock signal CLK.

FIG. 10 is a view illustrating an electric potential change in the clock signal CLK. A horizontal axis represents time, and the moment when the clock signal CLK is switched from the second state to the first state is plotted as zero. A vertical axis represents relative values of the electric potential, the second state (LOW) is equivalent to 0%, and the first state (HIGH) is equivalent to 100%. A graph expressed as “present embodiment” in FIG. 10 is one example in which the protection resistance 31 is introduced into the clock line CLK-L and thus the moderate delay is caused in the clock signal CLK. The potential change in the wiring in which an electrical resistance is R, and a parasitic capacitance is C is expressed in Expression 1 that follows.

$$V ( t ) = H \{ 1 - exp ( - \frac{t}{τ} ) \} τ = RC \qquad ( 1 )$$

Wherein H is a potential difference between the first state and the second state and τ is a time constant. According to the first embodiment, a parasitic capacitance of c=17.8 pF is attached to the clock line CLK-L, and a resistance of 15 kΩ is used as the protection resistance 31. Because the inherent resistance of the clock line CLK-L that has not the resistance 31 is 0.25 kΩ, the resistance of the clock line CLK-L is R=15.25 kΩ. The time constant is τ=271 ns from C and R. In this case, a difference between the clock signal CLK start 10% and 90% is approximately 600 ns. At this point, it is assumed that the number of the scan lines 16 is 1,090 and a frame frequency is 240 Hz. At this time, the selection time of one scan line 16 is 3.823 μs. In a case where the time constant of the clock line CLK-L is τ=271 ns, it takes 1.4 μs for the clock signal CLK to reach approximately 100% in a level (in a strict sense, 99.5% is rounded up to 100%). Therefore, because there still remains time room, 63% or more, even after the reaching of approximately 100% is performed with respect to the selection time 3.823 μs of the scan line 16, the malfunction of the shift register circuit SR does not occur that results from the delay in the clock signal CLK. In this manner, it is preferable that the protection resistance 31 is introduced in such a manner that approximately 60% or more of the selection duration reaches almost 100% of the electric potential and thus the moderate delay is caused in the clock signal CLK. In a case of switching the clock signal CLK, there is a concern that the transistor capacitances of the pass gates PG and memory controllers MC that are as many as the stages of the D latches (in this case, at least 1,091 or more) are simultaneously charged and discharged, and this causes a momentarily-large amount of electric current to occur and further the noise gets into the power source (the positive power source VDD and the negative power source VSSY for the scan line drive circuit). When the noise appears in the power source and the power source electric potential fluctuates, there is a concern that other circuits, using the power source, malfunction. Because when the moderate delay is caused in the clock signal CLK, the charge and discharge time is longer, a small amount of electric current flows for a comparatively long period of time, without the momentarily-large amount of electric current. That is, the other circuits normally operate without the noise getting into the power source. In other words, when the moderate delay is caused in the clock signal CLK, it is possible to improve a likelihood that the other circuits normally operate.

A graph expressed as “comparative embodiment” in FIG. 10 illustrates the electric potential change in a case where the protection resistance is not introduced into the clock line CLK-L. In this case, because a parasitic capacitance is C=17.8 pF and a wiring resistance is R=0.25 kΩ, the time constant is τ=4.5 ns, and the difference between the clock signal CLK start 10% and 90% is approximately 10 ns. Because the discharge and charge transistor capacitance is the same as that according to the first embodiment, the electric current that occurs momentarily (within a time of approximately 10 ns) is 60 times the electric current that occurs according to the first embodiment (within a time of approximately 600 ns). Conversely, according to the first embodiment, because an amount of electric current that occurs at the time of switching the clock signal CLK can be decreased by 1/60 of comparative example, a malfunction probability of the other circuit is greatly decreased without causing the noise in the power source according to the first embodiment.

### Comparative Example of Circuit Block Configuration

FIG. 15 is a plan view diagrammatically illustrating the circuit block configuration of the liquid crystal device according to the comparative example. Next, effects of the electro-optical device according to the first embodiment are described, referring to the comparative example in FIG. 15.

In the comparative example, illustrated in FIG. 15, the shift register circuit in the comparative example, illustrated in FIG. 14A, is used as the circuit on the Y side. Because of this, the liquid crystal device in the comparative example has the clock signal generation circuit. With the clock signal generation circuit, the first clock signal CLK1 and the second clock signal CLK2 are generated from the clock signal that is input to the clock line CLK-L, and a phase difference compensation is performed in such a manner that the phase difference between the two clock signals is decreased. At least the two inverters are cross-arranged in performing the phase difference compensation. Furthermore, the clock signal generation circuit has a lot of big buffers in order to supply the clock signal to the two shift register circuit, which are the circuits on the Y side. With this configuration, when switching the clock signal, a large amount of electric current is necessary and the noise gets into the power source.

In contrast, because the clock generation circuit is unnecessary in the electro-optical device, illustrated in FIG. 9, according to the first embodiment, the system-wide circuit scale of the electro-optical device can be decreased. Furthermore, the display defect due to the malfunction cannot occur, because the malfunction of the shift register circuit SR, which results from the two clock signals, cannot occur in the electro-optical device according to the first embodiment. In addition, the noise cannot appear in the power source, because the electro-optical device according to the first embodiment is not a clock signal generation circuit in which a large amount of electric current occurs momentarily.

Generally, when a display method of selecting every two scan lines, which is disclosed in JP-A-2012-49645, is adopted in the liquid crystal device 100, the clock signal is switched from the first state to the second state, midway in one horizontal duration. That is, in one horizontal duration, the clock signal is switched from the first state to the second state, or is switched from the second state to the first state. At this time, when the noise appears in the power source, a vertical band occurs that divides an image display region into two parts in the row direction, as illustrated in FIG. 15. This is because at the time of exchanging the clock, the noise appears in the power source. As described above, an occurrence of such a display defect can be suppressed, because the noise does not almost appear in the power source in the electro-optical device, described in FIG. 9, according to the first embodiment. In other words, the electro-optical device can be realized in which a high grade image display is performed.

In addition, in the comparative example illustrated in FIG. 15, the clock signal generation circuit cannot but be arranged to the upper side of the image display region, because the circuits on the Y side are arranged to the left and to the right of the image display region, respectively, and the circuit on the X side is arranged to the lower side of the image display region. Because of this, it is necessary to lead the clock line CLK-L around for a long time. In contrast, it is not necessary to lead the clock line CLK-L around for a long time, because the clock line CLK-L is one in the electro-optical device, illustrated in FIG. 9, according to the first embodiment, and thus the clock signal generation circuit is unnecessary. As one example, as illustrated in FIG. 9, an arrangement may be made outside of (to the lower side of) the signal line drive circuit 36, or may be made between the signal line drive circuit 36 and the display region 34.

### Construction of Electro-Optical Device

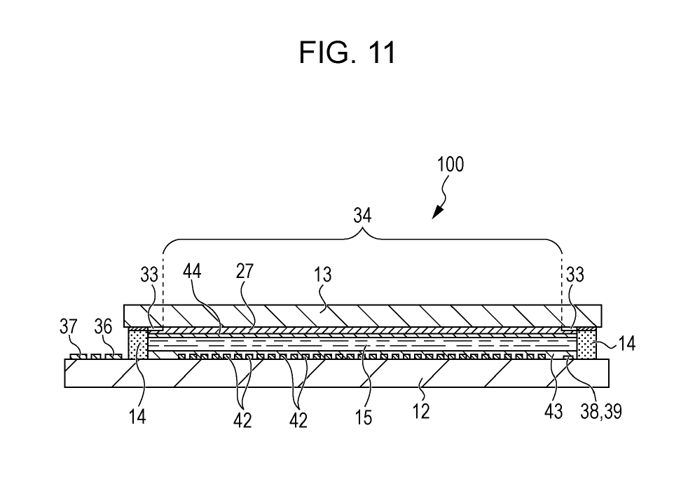

FIG. 11 is a cross-sectional view diagrammatically illustrating the liquid crystal device. A construction of the liquid crystal device is described below, referring to FIG. 11. Moreover, according to the embodiments described below, a case where the description “on something” is provided is defined to mean that a given component is arranged on something in such a manner as to come into contact with something, or that the given component is arranged on the something with another component in between, or that one part of the given component is arranged on something with another component in between, in such a manner as to come into contact with something.

In the liquid crystal device 100, element substrate 12 and the opposite substrate 13, which make up one pair of substrates, are attached to each other, by a sealant 14 arranged in the shape of a rectangle frame, when viewed from above. The liquid crystal device 100 has a configuration in which a liquid crystal layer 15 is enclosed within a region surrounded by the sealant 14. For example, liquid crystal material with positive dielectric anisotropy is used as the liquid crystal layer 15. In the liquid crystal device 100, a light blocking film 33, in the shape of a rectangular frame when viewed from above, which is made from light blocking material, is formed on the opposite substrate 13, along the vicinity of the inner periphery of the sealant 14, and the inside region of the light blocking film 33 is the display region 34. The blocking film 33, for example, is formed from aluminum (Al) that is the light blocking material, and is provided within the display region 34, facing toward the scan line 16 and the signal line 17, in such a manner as to define the outer periphery of the display 34, which faces the opposite substrate 13, and further in the manner described above.

As illustrated in FIG. 11, multiple pixel electrodes 42 are formed on the element substrate 12, the side of which faces the liquid crystal layer 15, and a first orientation film 43 is formed in such a manner as to cover the pixel electrodes 42. The pixel electrode 42 is a conductive film, which is made from a transparent conductive material such as indium tin oxide (ITO). On the other hand, the light blocking film 33 in the shape of a lattice is formed on the opposite substrate 13, the side of which faces the liquid crystal layer 15, and a common electrode 27 in the shape of a plane mat is formed on top of the light blocking film 33. Then, a second orientation film 44 is formed on the common electrode 27. The common electrode 27 is a conductive film, which is made from the transparent conductive material such as ITO.

The liquid crystal device 100 is a transmission type, polarization plates (not illustrated) and others are arranged on the element substrate 12 and the opposite substrate 13, the sides of which face the incoming light and the outgoing light, respectively. Moreover the configuration of the liquid crystal device 100 is not limited to this and a reflection type or transmission type configuration may be possible.

### Circuit Configuration

FIG. 12 is a diagram of an equivalent circuit illustrating an electrical configuration of the liquid crystal device. The electric configuration of the liquid crystal device is described below, referring to FIG. 12.

As illustrated in FIG. 12, the liquid crystal device 100 has multiple pixels 35 that make up a display region 34. A pixel electrode 42 is arranged in each of the pixels 35. Moreover, a TFT element 46 is formed in each of the pixels 35.

A TFT element 46 is a switching element that performs control of conduction to the pixel electrode 42. A signal line 17 is electrically connected to a source of the TFT element 46. For example, image signals S1, S2, and so forth up to Sn are supplied from signal line drive circuit 36 to each of the signal lines 17.

Moreover, a signal line 16 is electrically connected to a gate of the TFT element 46. For example, scan signals G1, G2, and so forth up to Gm are supplied from the scan line drive circuit 38 to the scan line 16, in the form of a pulse at a predetermined timing. Moreover, the pixel electrode 42 is electrically connected to a drain of the TFT element 46.

The scan signals G1, G2, and so forth up to Gm, which are supplied from the scan line 16, turn on the TFT element 46, which is the switching element, only for a predetermined period of time, and thus the image signals 51, S2, and so forth up to Sn, which is supplied from the signal line 17, are written to the pixel 35, through the pixel electrode 42, at a predetermined timing.

The image signals S1, S2, and so forth up to Sn, each of which has a predetermined electric potential, and is written to the pixel 35, are retained in a liquid crystal capacity formed between the pixel electrode 42 and the common electrode 27 (refer to FIG. 11), for a certain period of time. Moreover, a retention capacity 48 is formed from the pixel electrode 42 and the capacity line 47, in order to suppress in a decrease in the electric potential of the retained image signals S1, S2, and so forth up to Sn, due to leakage electric current.

When a voltage signal is applied to the liquid crystal layer 15, a level of the applied voltage level changes an orientation state of a liquid crystal molecule. This modulates light that is incident on the liquid crystal layer 15 and thus generates image light.

Moreover, according to the first embodiment, the shift register circuit SR is adapted to the scan line drive circuit 38, but the shift register circuit SR may be adapted to the signal line drive circuit 36. Furthermore, the liquid crystal device 100 is used for the description, as the electro-optical device, but an electrophoresis display device and an organic EL device may be used for the description target, as other electro-optical devices.

### Electronic Apparatus

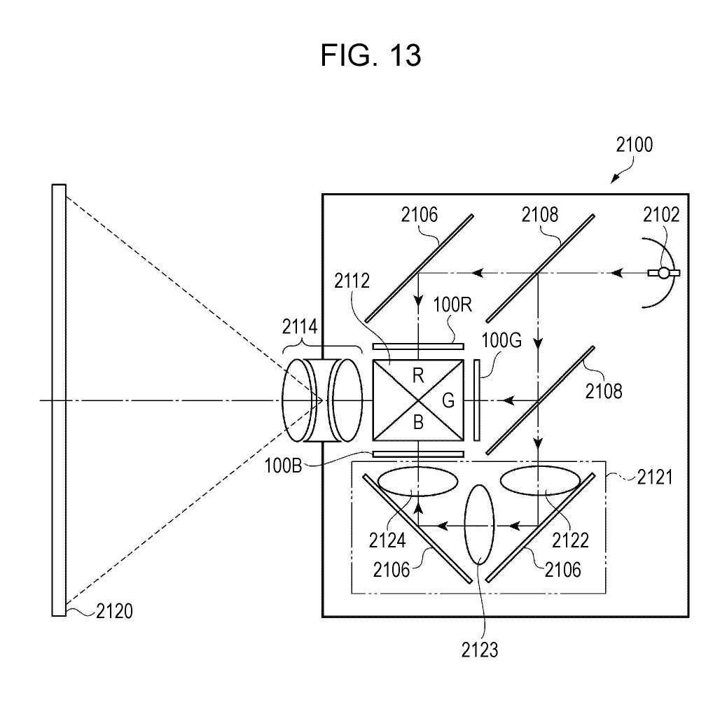

FIG. 13 is a plan view illustrating a configuration of a 3-chip projector as the electronic apparatus. Next, referring to FIG. 13, a projector is described as one example of the electronic apparatus according to the embodiment.

In a projector 2100, light emitted from a light source 2102 that is configured from an extra-high pressure mercury lamp is separated into three primary colors, red (R), green (G), and blue (B), by three mirrors 2106 arranged inside the projector 2100, and two dichroic mirrors 2108, and then the separated light are guided into liquid crystals 100R, 100G, and 100B that correspond to the primary colors. In addition, because blue color light is longer in light path than the other red color light and green color light, in order to prevent loss in the B color light, the B color light is guided through a relay lens system 2121 that is made from a light-incident lens 2122, a relay lens 2123, and an emission lens 2124.

Liquid crystal devices 100R, 100G and 100B each have the configuration described above, and are driven with image signals corresponding to red, green, and blue colors supplied from an external device (an illustration thereof is omitted), respectively.

The light modulated by the liquid crystal devices 100R, 100G, and 100B are incident on a dichroic prism 2112, from 3 directions. Then, in the dichroic prism 2112, while the red color light and blue color light are refracted by 90 degrees, the green color light goes straight. The light expressing a color image that is synthesized in the dichroic prism 2112 is enlargedly projected by a lens unit 2114, and the full color image is displayed on a screen 2120.

In addition, because while the image that has passed through the liquid crystal devices 100R and 100B is reflected by the dichroic prism 2112 and then is projected, the image that has passed the liquid crystal device 100G is projected, as it is, a setting is provided in such a manner that the images formed by the liquid crystal devices 100R and 100B and the image formed by the liquid crystal device 100G is in a left-right reversal relationship.

Since the projector 2100 according to the second embodiment uses the liquid crystal devices 100R, 100G, and 100B described above, it is possible to project the full color image that is bright, of high-definition and thus is high in image grade.

In addition to the projector that is described referring to FIG. 13, the electronic apparatus are enumerated, such as a rear projection type television, a direct view type television, a mobile phone, a portable audio apparatus, a personal computer, a monitor of a video camera, a car navigation apparatus, a pager, a personal digital assistance, an electronic calculator, a wordprocessor, a workstation, a television phone, a POS terminal, and a digital still camera. Then, the liquid crystal device 100 and shift register circuit SR, described in detail, according to the first embodiment, can be applied also to the electronic apparatuses described above.

Moreover, the invention is not limited to the embodiments described above, and various modifications to and improvements over the embodiments described in detail are possible.

This application claims priority from Japanese Patent Application No. 2012-145112 filed in the Japanese Patent Office on Jun. 28, 2012, the entire disclosure of which is hereby incorporated by reference in its entirely.

What is claimed is:

1. A shift register circuit comprising:
first to p-th (p is an integer that is 2 or greater) D latches; and
a clock line,
wherein each of the first to p-th D latches includes,
a input portion, and
a output portion,
wherein the output portion of the i-th (i is an integer from 1 to (p−1)) D latch and the input portion of the (i+1)-th D latch are electrically connected to each other,
wherein each of the first to p-th D latches includes, at least
a pass gate,
first to 2k-th (k is an integer that is 1 or greater) inverters, and
a memory controller,
wherein the pass gate and the first to 2k-th inverters are electrically connected in series between the input portion and the output portion, the memory controller is eletrcially connected in parallel to the first to 2k-th inverters between the pass gate and the output portion, and a control electrode of the pass gate and a control electrode of the memory controller are electrically connected to the clock line,
wherein the first to p-th D latches in the odd-numbered stage are first type D latches and the first to p-th D latches in the even-numbered stage are second type D latches,
wherein the pass gate of the first type D latch is made from a first conductivity type transistor and the memory controller of the first type D latch is made from a second conductivity type transistor, and
wherein the pass gate of the second type D latch is made from the second conductivity type transistor, and the memory controller of the second type D latch is made from the first conductivity type transistor.

2. The shift register circuit according to claim 1,
wherein one of source and drain regions of the pass gate is the input portion, and the other of the source and drain regions of the pass gate and one of source and drain regions of the memory controller are electrically connected to each other,
wherein the other of the source and drain regions of the memory controller is the output portion,
wherein the control electrode of the pass gate is a gate electrode, and
wherein the control electrode of the memory controller is a gate electrode.

3. The shift register circuit according to claim 2,
wherein each of the 2k inverters includes,
an inverter input electrode, and
an inverter output electrode,
wherein the inverter output electrode of the n-th (n is an integer from first to (2k−1)-th) inverter and the inverter input electrode of the (n+1)-th inverter are electrically connected to each other,
wherein the inverter input electrode of the first inverter, the other of the source and drain regions of the pass gate, and the one of the source and drain regions of the memory controller are electrically connected to each other, and
wherein the inverter output electrode of the 2k-th inverter and the other of the source and drain regions of the memory controller are electrically connected.

4. The shift resister circuit according to claim 1,
wherein the first conductivity type transistor is an N-type transistor, the second conductivity type transistor is a P-type transistor.

5. A shift register circuit comprising:
First to p-th (p is an integer that is 2 or greater) D latches,
wherein each of the first to p-th D latches includes,
a input portion, and
a output portion,
wherein the output portion of the i-th (i is an integer between 1 and (p−1)) D latch and the input portion of the (i+1)-th D latch are electrically connected to each other,
wherein each of the p D latches includes at least
a pass gate,
2k (k is an integer that is 1 or greater) inverters, and
a memory controller,
wherein a clock signal is supplied to the pass gate and the memory controller,
wherein the pass gate allows or disallows passing of data that is input to the input portion, according to the clock signal,
wherein the memory controller causes the 2k inverters to function as buffer circuits or storage circuits, according to the clock signal,
wherein the p-th D latches in the odd-numbered stage are first type D latches and the p D latches in the even-numbered stage are second type D latches,
wherein the pass gate of the first type D latch and the pass gate of the second type D latch operate mutually complementarily, and
wherein the memory controller of the first type D latch and the memory controller of the second type D latch operate mutually complementarily.

6. The shift register circuit according to claim 5,
wherein when the pass gate allows the passing of the data, the memory controller causes the 2k inverters to function as the buffer circuits, and
wherein when the pass gate disallows the passing of the data, the memory controller causes the 2k inverters to function as the storage circuits.

7. The shift register circuit according to claim 5,
wherein when the pass gate of the first type D latch allows the passing of the data that is input to the input portion of the first type D latch, the pass gate of the second type D latch disallows the passing of the data that is input to the input portion of the second type D latch, and
wherein when the pass gate of the first type D latch disallows the passing of the data that is input to the input portion of the first type D latch, the pass gate of the second type D latch allows the passing of the data that is input to the input portion of the second type D latch.

8. The shift register circuit according to claim 5,
wherein when the memory controller of the first type D latch causes the 2k inverters of the first type D latch to function as the buffer circuits, the memory controller of the second type D latch causes the 2k inverters of the second type D latch to function as the storage circuits, and
wherein when the memory controller of the first type D latch causes the 2k inverters of the first type D latch to function as the storage circuits, the memory controller of the second type D latch causes the 2k inverters of the second type D latch to function as the buffer circuits.

9. The shift register circuit according to claim 5,
wherein an ability of the pass gate of the first type D latch to allow the passing of the data is better than an ability of the pass gate of the second type D latch to allow the passing of the data.

10. An electro-optical device comprising:
the shift register circuit according to claim 1.
